(19) United States
(12) Patent Application Publication
(10) Pub. No.: US 2025/0231804 A1
(43) Pub. Date: Jul. 17, 2025

(54) METHOD AND APPARATUS WITH NEURAL NETWORK ACCELERATION

(71) Applicant: Samsung Electronics Co., Ltd., Suwon-si (KR)

(72) Inventors: Seok Ju YUN, Suwon-si (KR); Soon-Wan KWON, Suwon-si (KR); Sungmeen MYUNG, Suwon-si (KR); Jaehyuk LEE, Suwon-si (KR)

(73) Assignee: Samsung Electronics Co., Ltd., Suwon-si (KR)

(21) Appl. No.: 18/811,565

(22) Filed: Aug. 21, 2024

(30) Foreign Application Priority Data
Jan. 15, 2024 (KR) 10-2024-0006218

(51) Int. Cl. G06F 9/50

(52) U.S. Cl. CPC G06F 9/5027; G06F 9/5094; G06F 2209/504

(57) ABSTRACT

A neural network accelerator including always-on circuitry configured to determine pre-processed data, buffer circuitry including a plurality of banks configured to store the determined pre-processed data, and processor circuitry including a neural network model and configured to perform power-gating, the neural network model being configured to perform a neural network computation on the pre-processed data.

### CROSS-REFERENCE TO RELATED APPLICATIONS

This application claims the benefit under 35 USC § 119 (a) of Korean Patent Application No. 10-2024-0006218, filed on Jan. 15, 2024, in the Korean Intellectual Property Office, the entire disclosure of which is incorporated by reference herein for all purposes.

### BACKGROUND

### 1 Field

The following description relates to a method and apparatus with a neural network accelerator.

### 2. Description of Related Art

Typically, neural networks (NNs) in various forms are trained by machine learning and/or deep learning in various fields of application. These NN's may provide high performance characteristics, such as increased accuracy, speed, and/or energy efficiency, Algorithms that enable the machine learning of the NNs typically have a large number of computational operations, but the algorithms may be performed by processing using uncomplicated computations. Typically, these uncomplicated computations may include, for example, a multiply-accumulate (MAC) computation of multiplying two vectors and accumulating and adding up the resulting values thereof. Simple computations such as a MAC computation may be implemented through in-memory computing (IMC).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a neural network accelerator including always-on circuitry configured to determine pre-processed data, buffer circuitry including a plurality of banks configured to store the determined pre-processed data, and processor circuitry including a neural network model and configured to perform power-gating, the neural network model being configured to perform a neural network computation on the pre-processed data.

The processor circuitry may include a non-volatile memory (NVM) and one or more processor elements configured to perform power-gating on the NVM, and the neural network computations may be executed by the one or more processor elements with respect to the stored pre-processed data and parameters of the neural network stored in the NVM.

The processor circuitry may include any one or any combination of any two or more of the one or more processor elements as respective one or more in-memory processor elements, within the NVM, configured to perform in-memory computing (IMC), a first clock generator configured to generate a first clock for driving the NVM and the one or more processor elements, and a power management unit (PMU) configured to provide a power voltage for the NVM, one or more processor elements, and the first clock generator.

The PMU may be configured to provide the power voltage for the NVM, the one or more in-memory processor elements, and the first clock generator.

The buffer circuitry may include dual port PING-PONG static random-access memory (SRAM) configured to simultaneously perform a first operation of writing the pre-processed data into the plurality of banks through a first port and a second operation of reading the pre-processed data stored in the plurality of banks through a second port.

The buffer circuitry may be configured to operate with a second voltage and a second clock in response to performing the first operation and operate with a first voltage, the first voltage having a first value higher than a second voltage of the second voltage and a first clock faster than the second clock in response to performing the second operation of reading the pre-processed data stored in the plurality of banks and transferring the pre-processed data to the one or more in-memory processor elements.

The buffer circuitry may be configured to alternately repeat the first operation, the second operation, and a third operation of powering down until the pre-processed data is written again into the plurality of banks after the second operation is performed.

The PMU may be configured to turn off power to the NVM and the one or more in-memory processor elements during an idle period excluding an active period and the processor circuitry may perform the neural network computation during the active period.

The PMU may be configured to turn off power to the first clock generator during an idle period excluding an active period and the processor circuitry may perform the neural network computation during the active period.

The first clock generator may be configured to provide the first clock of a first voltage for the NVM and the one or more in-memory processor elements to operate at high speed during an active period and the processor circuitry may perform the neural network computation during the active period.

The always-on circuitry may be configured to provide voice data, the voice data being obtained by converting a voice audio signal into a digital signal and extracting a feature, as the pre-processed data to the processor circuitry.

The always-on circuitry may include an analog front end (AFE) configured to convert the voice audio signal into the digital signal, a pre-processor circuitry configured to perform pre-processing to extract a feature of the digital signal, and a second clock generator configured to generate a second clock for driving the AFE and the pre-processor circuitry.

The neural network accelerator may include voice activity detection (VAD) circuitry configured to determine whether the voice audio signal is present or absent and the VAD circuitry is configured to wake up the always-on circuitry responsive to a determination that the voice audio signal is present.

In a general aspect, here is provided a method including generating pre-processed data by converting a voice audio signal into a digital signal and extracting a feature, storing the pre-processed data in a plurality of banks, and performing, by a neural network model, a neural network computation on the pre-processed data.

The performing of the neural network computation may include transferring, by a first clock, the pre-processed data stored in the plurality of banks to one or more in-memory processor elements and performing, by the first clock, the neural network computation including a multiply-accumulate (MAC) computation between the pre-processed data and a stored weight.

The storing of the pre-processed data in the plurality of banks may include simultaneously performing a first operation of writing the pre-processed data in the plurality of banks through a first port and a second operation of reading the pre-processed data stored in the plurality of banks through a second port.

The storing of the pre-processed data in the plurality of banks may include performing the first operation with a second voltage and a second clock and performing the second operation of reading the pre-processed data stored in the plurality of banks with a first voltage having a first voltage value higher than a second voltage value of the second voltage and a first clock faster than the second clock and transferring the pre-processed data to the one or more in-memory processor elements.

The storing of the pre-processed data in the plurality of banks may include alternately repeating the first operation, the second operation, and a third operation of powering down until the pre-processed data is written again into the plurality of banks after the second operation is performed.

The method may include turning off power to non-volatile memory (NVM) and the one or more in-memory processor elements during an idle period excluding an active period during which the neural network computation is performed.

The method may include providing the first clock of a first voltage for NVM and the one or more in-memory processor elements to operate at high speed in an active period in which the neural network computation is performed.

### BRIEF DESCRIPTION OF THE DRAWINGS

FIG. 1 illustrates an example neural network accelerator according to one or more embodiments.

FIG. 2 illustrates an example electronic apparatus with neural network acceleration according to one or more embodiments.

FIGS. 3A to 3C illustrate example electronic apparatuses with static random-access memory (SRAM) buffer circuits according to one or more embodiments.

FIG. 4 illustrates an example method of a neural network accelerator according to one or more embodiments.

FIG. 5 illustrates an example electronic apparatus with neural network acceleration according to one or more embodiments.

FIG. 6 illustrates an example electronic apparatus with neural network acceleration according to one or more embodiments.

FIG. 7 illustrates an example electronic apparatus with neural network acceleration according to one or more embodiments.

FIG. 8 illustrates an example electronic apparatus with neural network acceleration according to one or more embodiments.

FIG. 9 illustrates an example method of a neural network accelerator according to one or more embodiments.

FIG. 10 illustrates an example electronic apparatus with neural network acceleration according to one or more embodiments.

Throughout the drawings and the detailed description, unless otherwise described or provided, it may be understood that the same or like drawing reference numerals refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used in connection with various example embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to one embodiment, the module may be implemented in a form of an application-predetermined integrated circuit (ASIC).

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

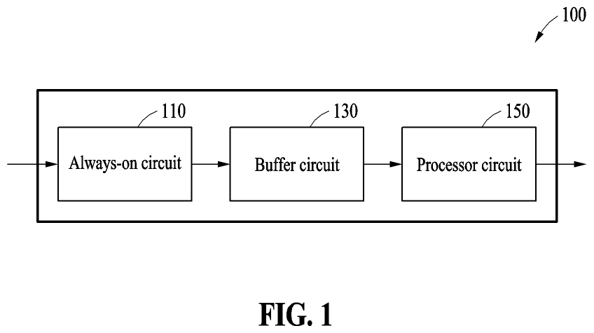

FIG. 1 illustrates an example neural network accelerator according to one or more embodiments. Referring to FIG. 1, in a non-limiting example, a neural network accelerator 100 may include an always-on circuitry 110, a buffer circuitry 130, and a processor circuitry 150. Herein, electronic devices, such as neural network accelerator 100, are representative of one or more processors, or one or more processors and a memory storing instructions, configured to implement one or more, or any combination of, operations or methods described herein. The one or more processors may be respective special purpose hardware-based computers or other special-purpose hardware. The one or more processors may be configured to execute such instructions. The one or more memories may store the instructions, which when executed by the one or more processors configure the one or more processors to perform one or more, or any combination of operations of methods described herein.

In an example, the always-on circuitry 110 may provide pre-processed data. The always-on circuitry 110 may provide the pre-processed data to the buffer circuitry 130. In an example, the always-on circuitry 110 may provide voice data, the voice data being obtained by converting a voice audio signal into a digital signal and extracting a feature, as the pre-processed data to the processor circuitry 150. In an example, the always-on circuitry 110 may be a voice trigger system (VTS) that pre-processes voice data, sequentially receives data for each frame at low speed, and recognizes a voice keyword through a voice recognition algorithm. However, examples are not limited thereto.

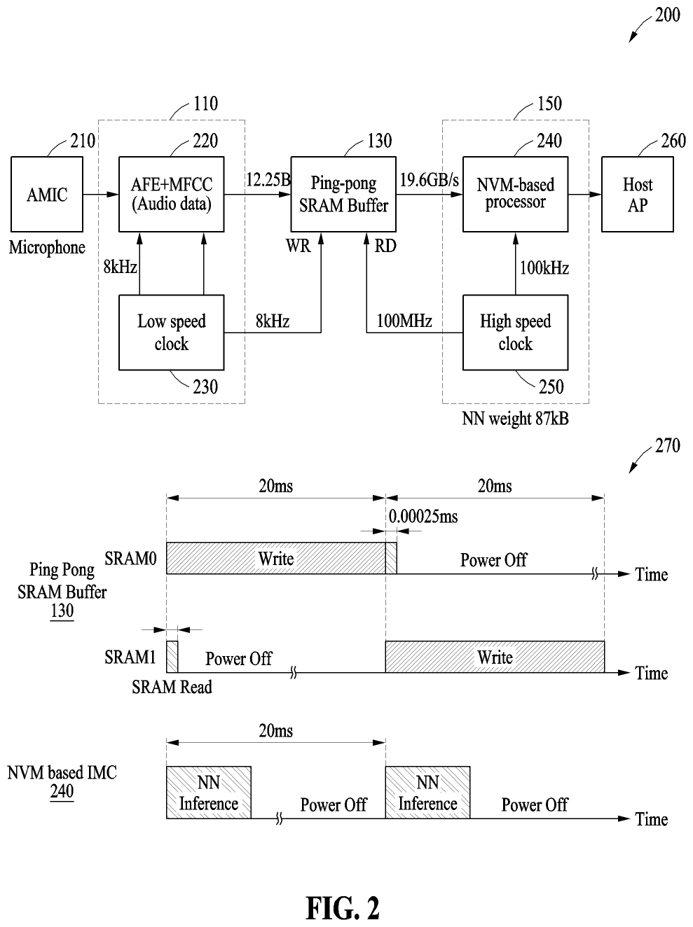

FIG. 2 illustrates an example electronic apparatus with neural network accelerator according to one or more embodiments.

Referring to FIG. 2, in a non-limiting example, an electronic apparatus 200 may include a buffer circuitry 130, and the buffer circuitry 130 may include a plurality of banks that store data pre-processed by the always-on circuitry 110. Here, “bank(s)” may be memory banks corresponding to blocks of memories in the same area when a memory area is divided into a plurality of blocks. The memory bank may have multiple pairs of identical addresses representing memory areas. In an example, when a 64-bit input/output occurs, the memory bank may correspond to a logical bundle of one or more memories within a channel. A channel may be a bundle that shares a single data path. The memory bank may be used in multiple pairs or sets.

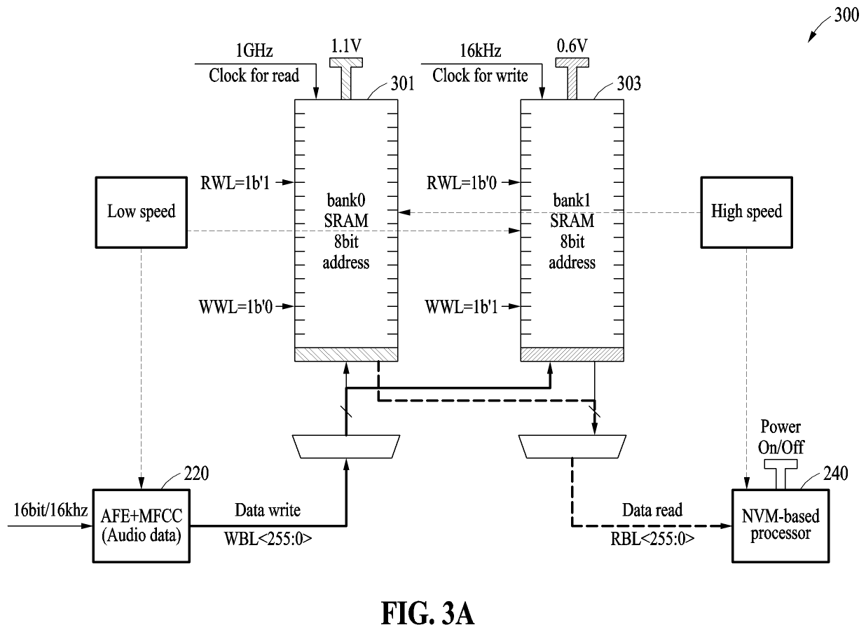

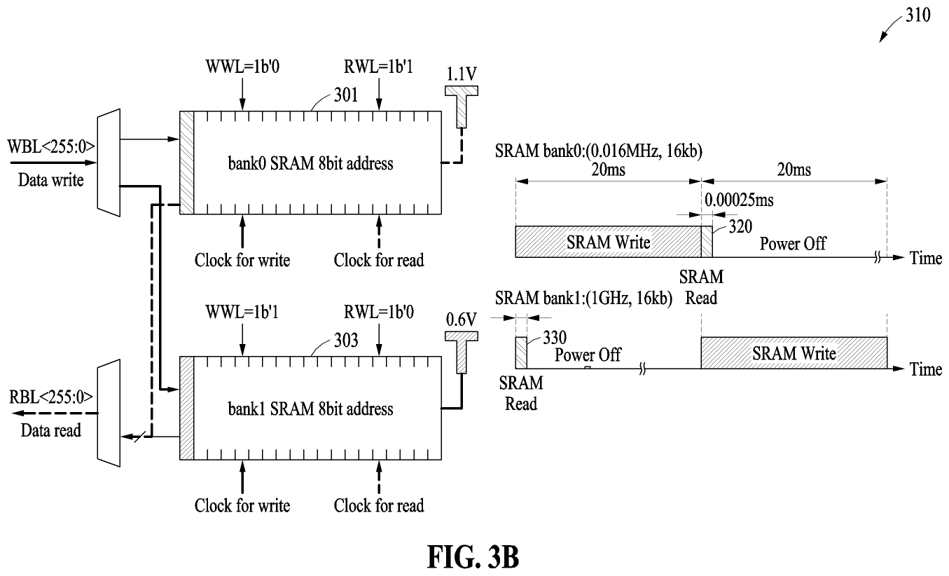

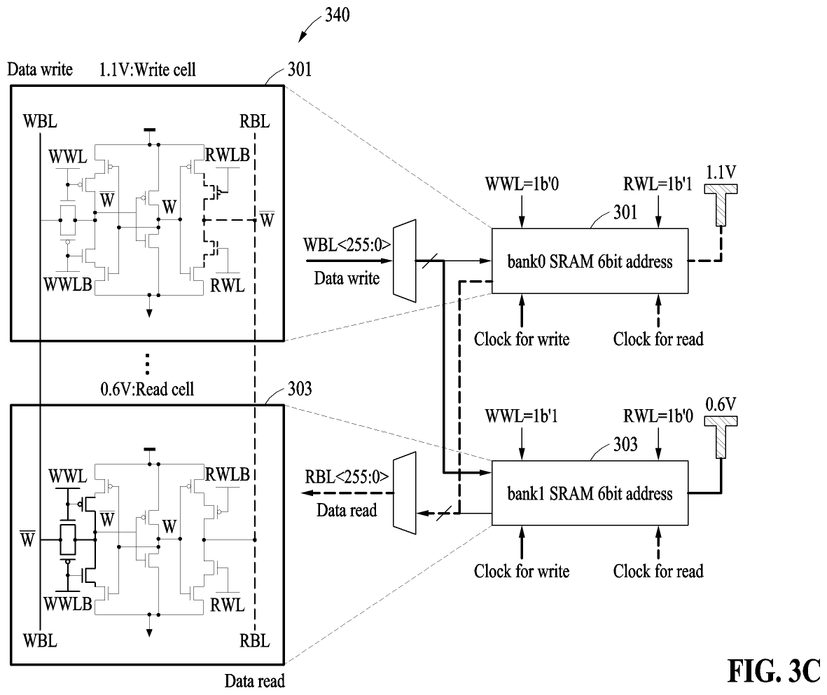

In an example, the buffer circuitry 130 may include dual port PING-PONG static random-access memory (SRAM) that simultaneously performs a first operation of writing the pre-processed data into the plurality of banks through a first port (e.g., a write (WR) port) and a second operation of reading the pre-processed data stored in the plurality of banks through a second port (e.g., a read (RD) port). The dual port PING-PONG SRAM may be a type of SRAM and may have two independent data buses. Thus, the dual port PING-PONG SRAM may correspond to memory that may read and write two pieces of data at the same time. In an example, using the dual port PING-PONG SRAM may enable two different devices to access the buffer circuitry 130 simultaneously. Here, the term “PING-PONG” may refer to two data buses being used alternately. In an example, the buffer circuitry 130 may include a 12T cell-based SRAM in which the first port (e.g., the WR port) is separate from the second port (e.g., the RD port). However, examples are not limited thereto. A structure and an operation of the buffer circuitry 130 are described in greater detail below with reference to FIGS. 3A to 3C.

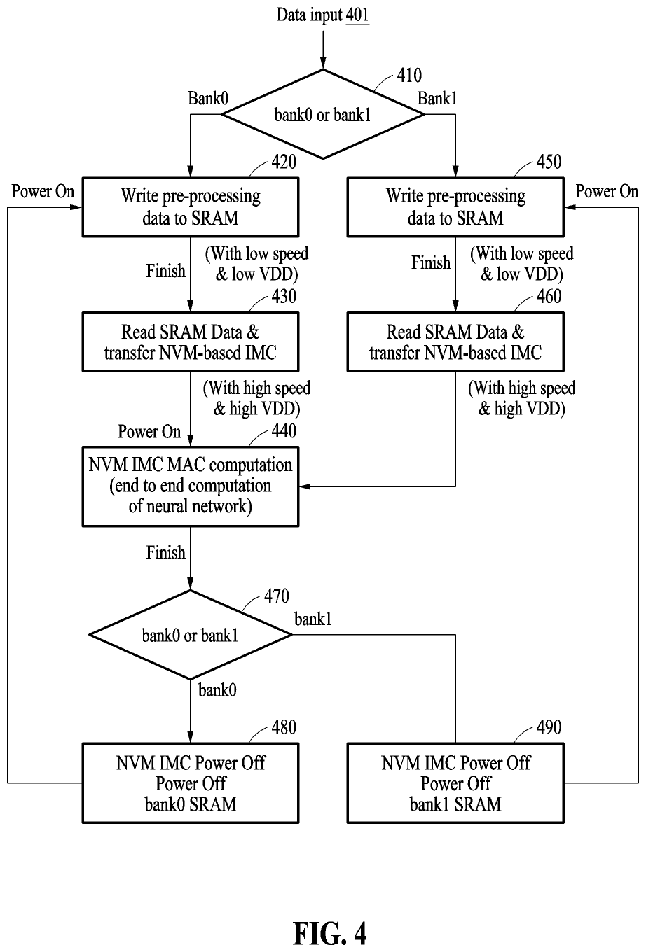

In an example, the processor circuitry 150 may include a machine learning model (e.g., a neural network model) that performs a neural network operation on the pre-processed data stored in the buffer circuitry 130 and may perform power-gating. Here, a “neural network operation” may be understood as operations encompassing and including various operations such as a multiply-accumulate (MAC) operation or convolution operation performed by an artificial neural network (ANN). “Power-gating” is one of the techniques for reducing power consumption and may correspond to a technique for reducing power consumption by cutting off power when a predetermined circuitry (e.g., the processor circuitry 150) is not used. A configuration and an operation of the processor circuitry 150 are described in greater detail below with reference to FIGS. 2 and 4.

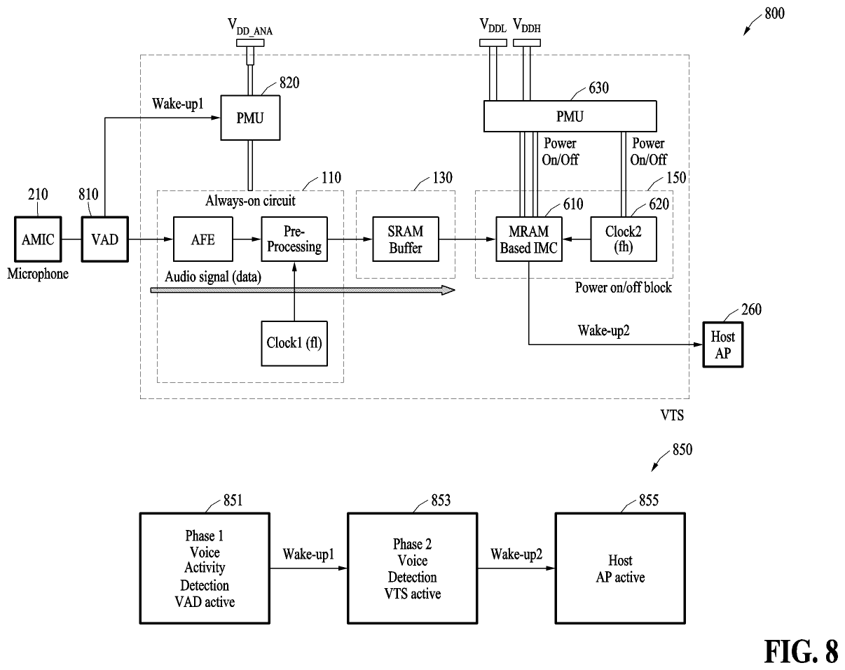

In an example, the neural network accelerator 100 may further include a voice activity detection (VAD) circuitry (e.g., a VAD circuitry 810 of FIG. 8) that determines whether a voice audio signal is present or absent. When determining that the voice audio signal is present, the VAD circuitry may wake up the always-on circuitry 110. An operation of the VAD circuitry is described in greater detail below with reference to FIG. 8.

Referring back to FIG. 2, in an example, the electronic apparatus 200 may include the always-on circuitry 110, the buffer circuitry 130, and the processor circuitry 150.

In an example, the always-on circuitry 110 may include an analog front end (AFE) and a mel-frequency cepstral coefficient (MFCC) block 220 and a second clock generator 230.

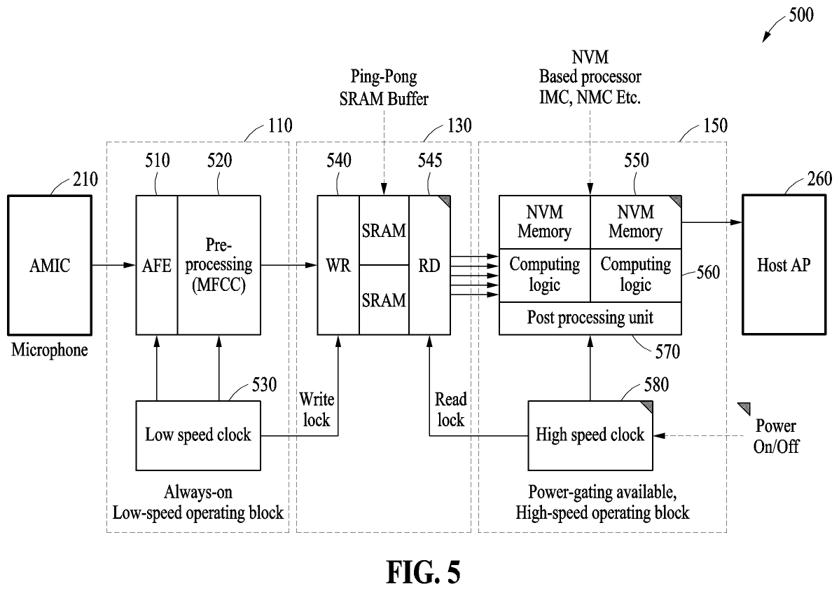

In an example, the AFE of the AFE and MFCC block 220 may convert a voice audio signal received from an analog microphone (AMIC) 210 into a digital signal. An MFCC (i.e., of AFE and MFCC block 220) may correspond to a pre-processor and perform pre-processing to extract a feature for a digital signal. The MFCC may discard unnecessary information (e.g., white noise, noise, etc.) related to voice recognition and vectorize an important feature (e.g., voice information). The MFCC may divide input sound into predetermined short periods and vectorize a feature extracted by analyzing a spectrum for a predetermined period. The AFE and the MFCC may be configured as a single block as illustrated in FIG. 2 or individual blocks as illustrated and as described below in FIG. 5.

In an example, the second clock generator 230 may generate a low-speed second clock for driving the AFE and the MFCC block 220. The second clock may be used to perform a first operation of writing data pre-processed by the buffer circuitry 130 into a plurality of banks through a first port (e.g., a WR port). The second clock may be, in an example, a low-speed clock of 8 kilohertz (KHz). However, examples are not limited thereto.

In an example, the always-on circuitry 110 may transmit pre-processed data (e.g., voice data) to the buffer circuitry 130 at a low speed of 12.25 gigabytes per second (Gbyte/s).

In an example, the buffer circuitry 130 may store the pre-processed data received from the always-on circuitry 110 in the plurality of banks. The buffer circuitry 130 may have two independent data buses and simultaneously perform the first operation of writing the pre-processed data into the plurality of banks through the first port (e.g., the WR port) and a second operation of reading the pre-processed data stored in the plurality of banks through a second port (e.g., an RD port).

The buffer circuitry 130 may transfer, in an example, data stored in the plurality of banks to the processor circuitry 150 at a high speed of 19.6 Gbyte/s. The buffer circuitry 130 may store data transferred from the AFE and the MFCC block 220 and transfer the stored data to a non-volatile memory (NVM)-based memory processor 240.

In an example, the processor circuitry 150 may include the NVM-based memory processor 240 and a first clock generator 250.

In an example, the NVM-based memory processor 240 may include NVM and a memory processor, processor circuitry, and/or in-memory processor elements. The NVM-based memory processor 240 may include one or more in-memory processor elements. The NVM-based memory processor 240 may include a memory processor such as an in-memory computing (IMC) circuitry along with the NVM. The NVM may transfer the pre-processed data stored in the plurality of banks. The NVM may include, in an example, one of ferroelectric RAM (FRAM), magneto resistive RAM (MRAM), phase-change RAM (PRAM), and resistive RAM (RRAM). However, examples are not limited thereto.

The NVM-based memory processor 240 may include an operation circuitry (e.g., a neural network model, a processor, and/or the IMC circuitry) that performs a neural network operation including a MAC operation between the pre-processed data and a weight of a neural network model stored in the NVM. Here, the IMC circuitry may accelerate a matrix operation and/or a MAC operation that performs an addition of a number of multiplications for learning-inference of artificial intelligence (AI) all at once. An operation of multiplication and summation for a neural network may be performed through a memory array including bit cells in the IMC circuitry. The IMC circuitry may perform the operation of multiplication and summation by an operation function of the memory array including the bit cells and processors included in the memory array, thereby enabling machine learning of the neural network. The memory processor may be an accelerator with memory including AI neural network information and a processor located within or near the memory. Additionally, the memory processor 240 may perform power-gating on the NVM.

In an example, the NVM-based memory processor 240 may transfer a neural network operation result to a host application processor (AP) 260.

In an example, the first clock generator 250 may generate the first clock for driving the NVM-based memory processor 240. The first clock generator 250 may provide the first clock of a first voltage for the NVM-based memory processor 240 to operate at high speed during an active period during which the processor circuitry 150 performs a neural network operation. The first clock may be used to perform a second operation in which the processor circuitry 150 reads the pre-processed data stored in the plurality of banks through the second port (e.g., the RD port). For example, the first clock may be a high-speed clock of 100 megahertz (MHz) or more. However, examples are not limited thereto.

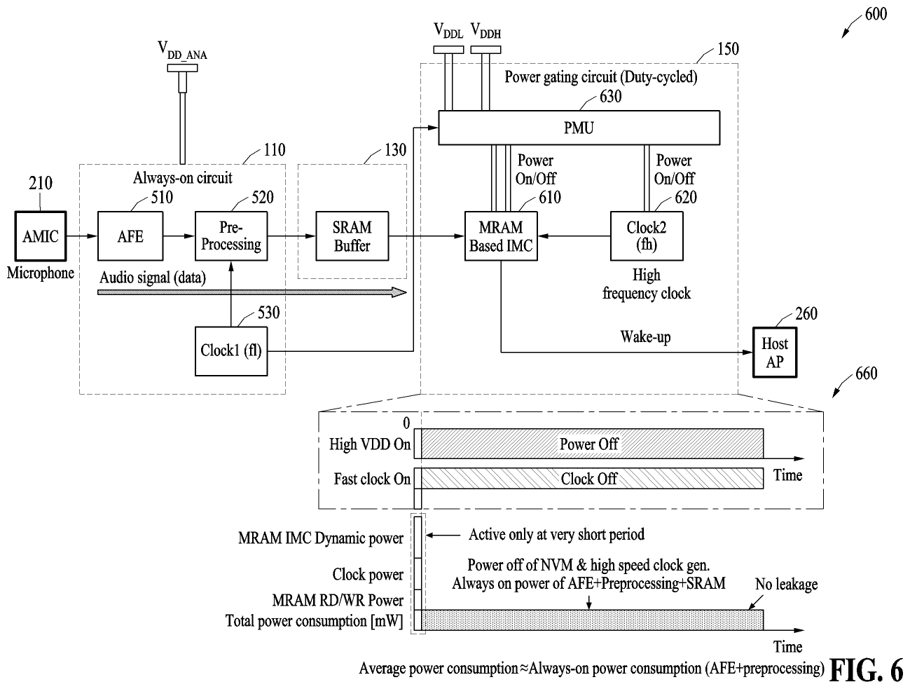

The NVM-based memory processor 240 may be configured as a single block as illustrated in FIG. 2 or individual blocks as described below in greater detail in FIGS. 5 and 6.

In an example, the processor circuitry 150 may further include a power management unit (PMU), as illustrated below in FIG. 6. The PMU may change a power voltage for the NVM-based memory processor 240 and the first clock generator 250.

In an example, the PMU may cut off the power to the processor circuitry 150 (e.g., the NVM-based memory processor 240) during an idle period that excludes the active period during which the processor circuitry 150 performs a neural network operation. The PMU may cut off the power to the first clock generator 250 during the idle period during which the processor circuitry 150 performs the neural network operation.

Referring to a timing diagram 270, which in an example, illustrates that the electronic apparatus 200 may write data into bank 0 of the buffer circuitry 130 for 20 milliseconds (ms) and then perform a neural network operation at high speed for a short period of time (e.g., 0.00025 ms) using the NVM-based memory processor 240. The electronic apparatus 200 may maintain the processor circuitry 150 in a power-off sleep state for most of the next 20 ms, with the exception of 0.00025 ms during which the computation (e.g., a neural network computation) is performed.

At the same time, the electronic apparatus 200 may read data from bank 1 of the buffer circuitry 130, transfer the data to the NVM of the NVM-based memory processor 240, and cut off the power to the buffer circuitry 130.

The electronic apparatus 200 may alternately perform writing and reading using ping-pong SRAM of the buffer circuitry 130.

In an example, two SRAM banks (e.g., SRAM bank 0 and SRAM bank 1) included in the buffer circuitry 130, data storing and data writing roles may be performed in a ping-pong manner (i.e., alternately performed). The two SRAM banks may have separate power supplies, and an RD port and a WR port may be separate such that reading and writing are performed simultaneously.

In an example, the buffer circuitry 130 may operate at low voltage and low speed when storing data and then operate at high voltage and high speed when reading data and transferring the data to the NVM-based memory processor 240. After transferring the data, the buffer circuitry 130 may power down before writing data again.

In an example, the NVM-based memory processor 240 may perform a neural network operation such as a MAC operation between a weight stored in the NVM and the transferred data and maintain a power-off sleep state.

In an example, the electronic apparatus 200 may minimize an active period and achieve low power consumption through a high-speed operation using a high-voltage, high-speed clock on data (e.g., a weight) stored in the NVM and the data transferred from the buffer circuitry 130. The electronic apparatus 200 may share, with the processor circuitry 150, a high voltage for writing data into the NVM and a high voltage for increasing an operating frequency.

FIGS. 3A to 3C illustrate example electronic apparatuses with static random-access memory (SRAM) buffer circuits, or circuitry, according to one or more embodiments.

Referring to FIG. 3A, in a non-limiting example, electronic apparatus 300 illustrates that the buffer circuitry 130 may be configured to have a dual port PING-PONG SRAM structure.

In an example, the buffer circuitry 130 may alternately perform writing and reading using dual port PING-PONG SRAM. In two SRAM banks (e.g., SRAM bank 0 301 and SRAM bank 1 303) included in the buffer circuitry 130, data storing and data writing roles may be performed in a ping-pong manner (alternately). The SRAM bank 0 301 and the SRAM bank 1 303 may have separate power supplies, so that a first port (e.g., a WR port) and a second port (e.g., an RD port) may be separate while enabling simultaneous reading and writing.

In an example, the SRAM bank 1 303 may write pre-processed data received through the WR port from an AFE and an MFCC block (e.g., AFE and MFCC block 220) through a write bit line (WBL)<255:0>. Data writing conducted between the AFE and the MFCC block and the SRAM bank 1 303 may be performed, in an example, by a low-speed clock of 16 bit/16 KHz at a voltage of 0.6 volts (V).

In an example, a NVM-based memory processor (e.g., NVM-based memory processor 240) may read the data stored in the SRAM bank 0 301 through the RD port into NVM through a read bit line (RBL)<255:0>. In this case, data reading conducted between the NVM-based memory processor and the SRAM bank 0 301 may be performed, in an example, by a high-speed clock of 16 bit/1 GHz at a voltage of 1.1 V.

The buffer circuitry 130 may operate at low voltage and low speed when storing data in an SRAM bank and operate at high voltage and high speed when reading the data from the SRAM bank and transferring the data to the NVM-based memory processor 240. After transferring the data, the buffer circuitry 130 may power down before writing data again.

Referring to FIG. 3B, in a non-limiting example, electronic apparatus 310 illustrates an operation of dual port PING-PONG SRAM.

In an example, SRAM bank 0 301 of the buffer circuitry 130 may write data using a low speed clock of 16 bit/16 kHz for 20 ms and then power down after the memory processor reads the data at high speed for a short period of time (e.g., 0.00025 ms 320). The SRAM bank 0 301 may remain in a power-off sleep state for most of the 20 ms following the previous 20-ms data writing period, with the exception of the 0.00025 ms 320.

At the same time, SRAM bank 1 303 of an SRAM buffer circuitry may power down after 0.00025 ms 330 during which the NVM-based memory processor reads the data from the previous 20-ms period and then stay powered for the subsequent 20-ms period during which data is written into the SRAM bank 1 303.

In an example, a neural network accelerator (e.g., the electronic apparatus 200 with neural network acceleration) may alternately perform writing and reading using the PING-PONG SRAM of the SRAM buffer circuitry. The SRAM buffer circuitry may alternately repeat a first operation of storing (writing) pre-processed data in banks through a first port, a second operation of reading the data (e.g., the pre-processed data) stored in the banks and transmitting the data to a memory processor, and a third operation of powering down until the pre-processed data is written again into the banks.

When performing the first operation of writing the pre-processed data into the banks through the first port, the SRAM buffer circuitry may operate with a second voltage and a second clock. When performing the second operation of reading the pre-processed data stored in the banks and transferring the data to the memory processor, the SRAM buffer circuitry may operate with a first voltage higher than the second voltage and a first clock faster than the second clock.

Referring to FIG. 3C, in a non-limiting example, an electronic apparatus 340 illustrates the transistor structures of SRAM bank 0 301 and SRAM bank 1 303 of the dual port PING-PONG SRAM. Typically, it may not be possible to perform WR and RD operations simultaneously in one 12-T SRAM. However, in an example, with two SRAM banks (e.g., the SRAM bank 0 301 and the SRAM bank 1 303) sharing a WBL and an RBL, WR and RD operations may be performed simultaneously.

In an example, the dual port PING-PONG SRAM may include 12T cell-based SRAM with separate RD and WR ports which may perform a low-speed WR operation and a high-speed RD operation simultaneously. In an example, when performing a WR operation on the SRAM bank 1 303, a WWL signal may open a WBL path, which may enable write data to be stored in the SRAM bank 1 303 via the open WBL path. In addition, an RWL signal may open an RBL path of the SRAM bank 0 301, thereby transferring data from the SRAM bank 0 301 to the outside.

By controlling the SRAM bank 0 301 and the WWL signal and the RWL signal for the SRAM bank 0 301, it may be possible, in an example, to individually select a bank (cell) for reading and a bank (or cell) for writing. Through this, WR and RD operations for cells included in different memory banks may be performed simultaneously.

FIG. 4 illustrates an example method of a neural network accelerator according to one or more embodiments. Operations to be described with reference to FIG. 4 and below may be performed sequentially but not necessarily. For example, the order of the operations may change and at least two of the operations may be performed in parallel, or one operation may be performed separately.

Referring to FIG. 4, in a non-limiting example, a neural network accelerator (e.g., the electronic apparatus 200 with neural network acceleration) may perform a neural network operation and power-gating through operations 410 to 490.

In an example, in operation 410, the neural network accelerator may determine whether to store input data 401 in SRAM bank 0 or SRAM bank 1 (e.g., SRAM bank 0 301 and SRAM bank 1 303). Here, the input data 401 may be data pre-processed by an always-on circuitry. However, examples are not limited thereto.

In an example, when determining whether to store the data in SRAM bank 0 in operation 410, the neural network accelerator may write the pre-processed data into SRAM bank 0 in operation 420. The neural network accelerator may write the pre-processed data into SRAM bank 0 at low speed and low VDD.

In an example, when the writing operation for SRAM bank 0 is terminated, the neural network accelerator may read the data stored in SRAM bank 0 and transfer the data to a processor circuitry in operation 430. The processor circuitry may be a NVM-based IMC device. However, examples are not limited thereto. The neural network accelerator may read the data stored in SRAM bank 0 at high speed and high VDD and transfer the data to the processor circuitry.

In an example, when the data is transferred to the processor circuitry, the neural network accelerator may supply power (power on) to the processor circuitry and perform a neural network operation (e.g., MAC operation) in operation 440. The neural network accelerator may perform the operation from the beginning to the end of an operation of the neural network.

In an example, when the neural network operation is terminated in operation 440, the neural network accelerator may determine whether to store an operation result in SRAM bank 0 or SRAM bank 1 in operation 470.

When determining to store the operation result in SRAM bank 0 in operation 470, the neural network accelerator may store the operation result in SRAM bank 0, power off a NVM-based memory processor, and, in an example, also power off SRAM bank 0 in operation 480. Then, the neural network accelerator may perform operation 420 when the power is supplied again.

When determining to store the data in SRAM bank 1 in operation 410, the neural network accelerator may write the pre-processed data in SRAM bank 1 in operation 450. The neural network accelerator may write the pre-processed data into SRAM bank 1 at low speed and low VDD.

In an example, when the writing operation for SRAM bank 1 is terminated in operation 450, the neural network accelerator may read the data stored in SRAM bank 1 and transfer the data to the processor circuitry in operation 460. The processor circuitry may be the NVM-based IMC device. However, examples are not limited thereto. The neural network accelerator may read the data stored in SRAM bank 1 at high speed and high VDD and transfer the data to the processor circuitry.

When the data is transferred to the processor circuitry in operation 460, the neural network accelerator may supply power (power on) to the processor circuitry and perform the neural network operation (e.g., a MAC operation) using the NVM-based memory processor (e.g., NVM-based memory processor 240) in operation 440.

In an example, when determining to store the operation result in SRAM bank 1 in operation 470, the neural network accelerator may store the operation result in SRAM bank 1, power off the NVM-based memory processor and also power off SRAM bank 1 in operation 490. Then, the neural network accelerator may perform operation 450 when the power is supplied again.

FIG. 5 illustrates an example electronic apparatus with neural network accelerator according to one or more embodiments.

Referring to FIG. 5, in a non-limiting example, an electronic apparatus 500 with neural network acceleration, the electronic apparatus 500 may include the always-on circuitry 110, the buffer circuitry 130, and the processor circuitry 150.

In an example, the always-on circuitry 110 may include an AFE 510, a pre-processor 520, and a second clock generator 530. The pre-processor 520 may correspond to the MFCC (e.g., AFE and MFCC block 220) as described above.

In an example, the AFE 510 may convert a voice audio signal received from the AMIC 210 into a digital signal. The pre-processor 520 may perform pre-processing to extract a feature of the digital signal. The pre-processor 520 may discard unnecessary information related to voice recognition and vectorize only important features. The pre-processor 520 may divide input sound into predetermined short periods and vectorize an extracted feature by analyzing a spectrum for a predetermined period. Similar to the AFE and the MFCC block 220 illustrated in FIG. 2, the AFE 510 and the pre-processor 520 may be configured as a single block or individual blocks as illustrated in FIG. 5.

In an example, the second clock generator 530 may generate a low-speed second clock for driving the AFE 510 and the pre-processor 520. The second clock may be used to perform a first operation of writing data pre-processed by the buffer circuitry 130 into a plurality of banks through a first port (e.g., a WR port 540). The second clock generator 530 may correspond to, for example, the second clock generator 230 described above with reference to FIG. 2.

In an example, the always-on circuitry 110 may transmit, for example, pre-processed data (e.g., voice data) to the buffer circuitry 130 at a low speed of 12.25 Gbyte/s.

In an example, the buffer circuitry 130 may store the pre-processed data received from the always-on circuitry 110 in the plurality of banks. The buffer circuitry 130 may have two independent data buses and simultaneously perform the first operation of writing the pre-processed data into the plurality of banks through a first port (e.g., the WR port 540) and a second operation of reading the pre-processed data stored in the plurality of banks through a second port (e.g., an RD port 545).

The buffer circuitry 130 may transfer data stored in the plurality of banks to the processor circuitry 150 at a high speed of 19.6 Gbyte/s. The buffer circuitry 130 may store the data transferred through the AFE 510 and the pre-processor 520 and transfer the stored data to the processor circuitry 150.

In an example, the processor circuitry 150 may include NVM 550, computing logic 560, a post-processing unit 570, and a first clock generator 580.

In an example, the NVM 550 may transfer the pre-processed data stored in the plurality of banks to the computing logic 560. The NVM 550 may include one of FRAM, MRAM, PRAM, and RRAM. However, examples are not limited thereto.

In an example, the computing logic 560 may correspond to a memory processor such as the IMC circuitry, as described above. The computing logic 560 may perform a neural network computation including a MAC computation between the pre-processed data and a weight stored in the NVM 550. The computing logic 560 may transfer a neural network computation result to a host AP 260.

In an example, the post-processing unit 570 may output a multi-bit computation result obtained by integrating the computation results of a plurality of computing logics 560.

In an example, the first clock generator 580 may generate a first clock for driving the NVM 550, the computing logic 560, and the post-processing unit 570. The first clock generator 580 may provide the first clock having a first voltage for the NVM memory 550, the computing logic 560, and the post-processing unit 570 which may operate at high speed during an active period during which the computing logic 560 performs a neural network computation. The first clock may be used to perform a second operation in which the computing logic 560 reads the pre-processed data stored in the plurality of banks through the second port (e.g., the RD port 545). In an example, the first clock generator 580 may correspond to the first clock generator 250 as described above with reference to FIG. 2.

FIG. 6 illustrates an example electronic apparatus with neural network accelerator according to one or more embodiments. Referring to FIG. 6, in a non-limiting example, electronic apparatus 600 with neural network acceleration illustrates a diagram of an operating period of the neural network accelerator 660.

The electronic apparatus with neural network acceleration 600 may include the always-on circuitry 110, the buffer circuitry 130, and the processor circuitry 150 as described above with reference to FIG. 5. In an example, the processor circuitry 150 may include an NVM-based memory processor 610 (e.g., an IMC circuitry), a first clock generator 620, and a PMU 630. The first clock generator 620 may generate a faster frequency clock (i.e., a first frequency clock) than a frequency clock of the second clock generator 530 (i.e., a second frequency clock).

In an example, data stored in the buffer circuitry 130 may be stored again in the NVM in the NVM-based memory processor 610. The data stored in the NVM may be used to perform a neural network computation in the memory processor 610 (e.g., an IMC circuitry). The NVM and the memory processor 610 may operate at the maximum high speed by the first clock generator 620. The processor circuitry 150 may power down during an idle period excluding an active period during which the neural network computation is processed.

When there is no power supply, the NVM-based memory processor 610 incurs no data loss and does not consume power. In addition, during the idle period, a high-speed clock generator (e.g., the first clock generator 620) may also power down or may be disabled.

The NVM plays a role of retrieving the data stored in the buffer circuitry 130 and transferring the data to the memory processor 610 and may be configured to power down during the idle period. When the writing operation speed of the NVM is slow, the power of the NVM may be selectively adjusted.

In an example, the memory processor 610 may store a parameter of a neural network as a weight and may perform a neural network computation along with the data retrieved from the NVM to perform inference for a neural network model.

The processor circuitry 150 may perform the entire neural network computation in a short period of time using a high-speed clock and may be configured to power down during the idle period, resulting in a significant reduction in average power consumption.

In an example, the PMU 630 may change a power voltage for the NVM-based memory processor 610 and the first clock generator 620.

The PMU 630 may turn off the power to the processor circuitry 150 during the idle period that may exclude the active period during which the memory processor 610 performs the neural network computation. The PMU 630 may turn off the power to the first clock generator 620 during the idle period, the idle period excluding the active period during which the processor circuitry 150 performs the neural network computation.

In an example, as shown in the diagram 660, the active period may correspond to less than 1% of the entire operating period and the idle period may correspond to 99% or more of the entire operating period. The duty ratio of the active period may be, for example, less than 200 microseconds (μs).

As described above, the always-on circuitry 110 may be, for example, a VTS that recognizes a voice keyword through a voice recognition algorithm.

Because the VTS processes a relatively low-speed voice signal, the overall operation speed may be as low as, for example, 20 ms latency. As a result, the VTS may have a relatively higher proportion of idle periods compared to implementing a neural network accelerator in a typical micro controller unit (MC)-based system. Consequently, using SRAM as a main memory may, in an example, increase both the proportion of leakage power and power consumption.

In an example, using NVM as the main memory and performing power-gating to power off the NVM during an idle period during which a digital block (e.g., the processor circuitry 150) does not operate may lead to a reduction in leakage current and a significant decrease in average power consumption compared to using SRAM.

In an example, average power consumption (P_{AVE}) may correspond to the total power, which includes dynamic power (P_{ac}) required for the operation of the buffer circuitry 130 and leakage current (P_{leakage}) generated in the buffer circuitry 130. A duty ratio D may be expressed by Equation 1 below, for example.

$$\begin{matrix}{P}_{AVE} = {P}_{ac}^{*} D + {P}_{leakage} \\ D = {T}_{ac} / {T}_{ac} + {T}_{idle}\end{matrix} \qquad Equation 1$$

The duty ratio D may correspond to the ratio of an active period (T_{ac}), excluding an idle period (T_{idle}), to the total period.

In an example, minimizing the ratio of the active period (T_{ac}) may lead to a reduction in leakage current and a significant decrease in average power consumption.

The electronic apparatus with neural network acceleration 600 may operate the memory processor 610 by selectively utilizing a clock generator (e.g., the first clock generator 620) capable of high-speed operation during the active period (T_{ac}), thereby minimizing the ratio of the active period (T_{ac}) to the total period. The active period (T_{ac}) may correspond to the total operating cycle/operating frequency of the memory processor 610. When operating frequency increases, the active period (T_{ac}) may decrease. Accordingly, because the ratio of the active period (T_{ac}) to the total period decreases, dynamic power consumption from the average power consumption is nearly eliminated. Only the leakage power of logic and/or the buffer circuitry 130, for which power-off is not possible during the idle period, and the power consumption of the AFE 510 remain. In this case, since the number of operating cycles remains the same, the number of switching times of the memory processor 610 stays constant. However, with the improvement in operating speed, increasing periods during which power is turned off may enhance the efficiency of power consumption from an energy perspective.

In summary, the neural network accelerator 600 may achieve a duty ratio D of D=T_{active}/(T_{active}+T_{idle})≈0 by utilizing minimal active periods along with power-gating for the NVM.

Accordingly, the average power consumption (P_{AVE}) may also be expressed as P_{AVE}=P_{ac}*D+P_{Leakage}≥0, and thus, power consumption may be similar to leakage power generated by leakage current (P_{leakage}) generated in the buffer circuitry 130.

The operating method and structure described above may be applied to, for example, a VTS and/or an always-on sensing system that operates at a very low duty ratio to enhance the efficiency of power consumption.

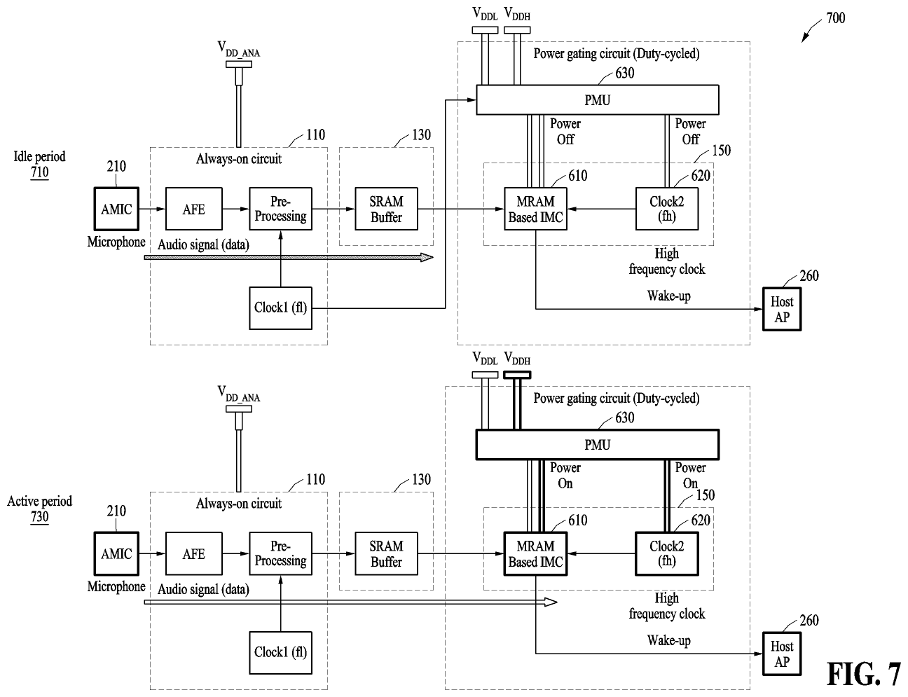

FIG. 7 illustrates an example electronic apparatus with neural network accelerator according to one or more embodiments. Referring to FIG. 7, in a non-limiting example, electronic apparatus 700 illustrates an operation of the neural network accelerator (e.g., the electronic apparatus 200 with neural network acceleration) during an idle period 710 and an operation of the neural network accelerator during an active period 730.

The electronic apparatus 700 may maintain only the always-on circuitry 110 and the buffer circuitry 130 in an active state during the idle period 710 and turn off the power to the processor circuitry 150, preventing power consumption by the processor circuitry 150.

On the other hand, during the active period 730, the electronic apparatus 700 may also activate the processor circuitry 150 in addition to the always-on circuitry 110 and the buffer circuitry 130 and perform a neural network computation.

During the active period 730, the neural network accelerator may provide a high-voltage, high-speed clock for the buffer circuitry 130 and the processor circuitry 150 to operate at high speed. In this case, even if the power is turned off, data in the NVM included in the processor circuitry 150 may be preserved.

FIG. 8 illustrates an example electronic apparatus with neural network accelerator according to one or more embodiments. Referring to FIG. 8, in a non-limiting example, electronic apparatus with neural network acceleration 800 illustrates a diagram 850 showing an operation of a multi-phase VTS.

In an example, the electronic apparatus 800 may further include VAD circuitry 810 and a PMU 820. The VAD circuitry 810 may determine whether a voice audio signal is present or absent in a signal received from the AMIC 210.

When the presence of the voice audio signal is determined (or detected), as shown in operation 851, the VAD circuitry 810 may wake up (wake-up 1) the always-on circuitry 110 or wake up (wake-up 2) the PMU 820 for the always-on circuitry 110, as illustrated in FIG. 8.

As the always-on circuitry 110 or the PMU 820 of the always-on circuitry 110 is woken up (wake-up 1), when a voice word is recognized by the VTS in operation 853, the neural network accelerator 800 may transmit wake-up 2 to a host AP and activate the host AP as shown in operation 855.

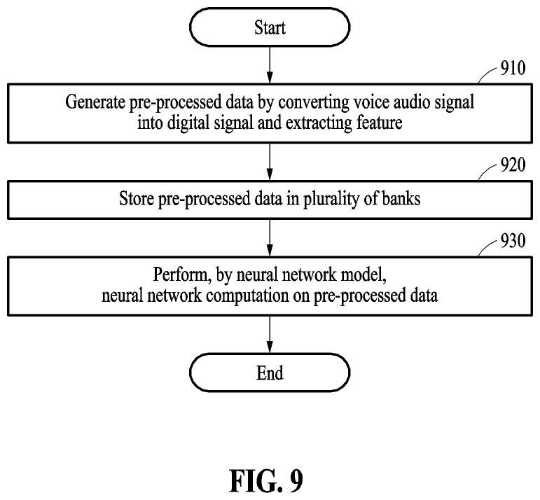

FIG. 9 illustrates an example method of a neural network accelerator according to one or more embodiments. Referring to FIG. 9, in a non-limiting example, a neural network accelerator (e.g., the electronic apparatus 200 with neural network acceleration) may perform a neural network computation through operations 910 to 930.

In an example, in operation 910, the neural network accelerator may generate pre-processed data by converting a voice audio signal into a digital signal and extracting a feature.

In an example, in operation 920, the neural network accelerator (e.g., the electronic apparatus 200 with neural network acceleration) may store the pre-processed data generated in operation 910 in a plurality of banks. The neural network accelerator may simultaneously perform a first operation of writing the pre-processed data into the plurality of banks through a first port and a second operation of reading the pre-processed data stored in the plurality of banks through a second port. The neural network accelerator may perform the first operation with a second voltage and a second clock. The neural network accelerator may perform the second operation of reading the pre-processed data stored in the plurality of banks with a first voltage higher than the second voltage and a first clock faster than the second clock and transferring the data to a memory processor. The neural network accelerator may alternately repeat the first operation, the second operation, and a third operation of powering down until the pre-processed data is written again into the plurality of banks after the second operation is performed.

In an example, in operation 930, the neural network accelerator (e.g., the electronic apparatus 200 with neural network acceleration) may perform a neural network computation on the pre-processed data stored in operation 920 by a neural network model. The neural network accelerator may transfer the pre-processed data stored in the plurality of banks to the memory processor using the first clock. The neural network accelerator may perform a neural network computation including a MAC computation between the pre-processed data and a stored weight using the first clock. The neural network accelerator may provide the first clock of the first voltage for NVM and the memory processor to operate at high speed during an active period during which the neural network computation is performed.

The neural network accelerator may turn off the power to the NVM and the memory processor during an idle period excluding the active period during which the neural network computation is performed.

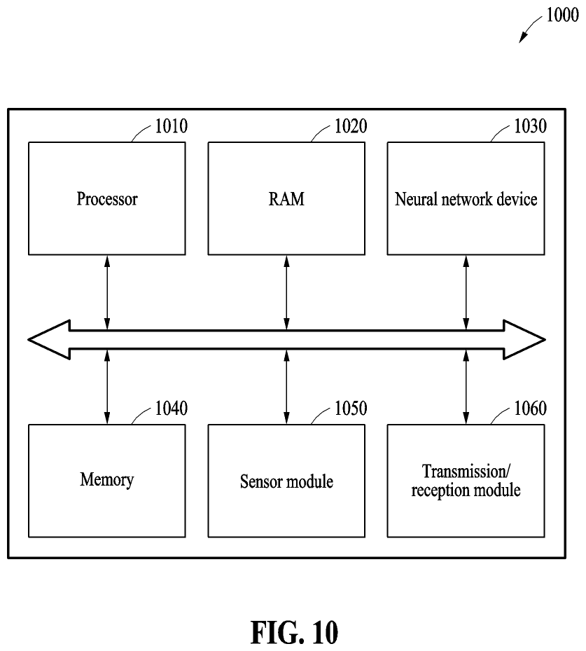

FIG. 10 illustrates an example electronic apparatus with neural network acceleration according to one or more embodiments. Referring to FIG. 10, in a non-limiting example, an electronic apparatus 1000 may extract valid information by analyzing input data (e.g., input sound) in real time based on a neural network device 1030 and determine a situation based on the extracted valid information or control components of an electronic device on which the electronic system 1000 is mounted.

In an example, the electronic apparatus with neural network acceleration 1000 may apply to, or be provided in, a drone, a robot apparatus such as an Advanced Drivers Assistance System (ADAS), a smart TV, a smartphone, a medical device, a mobile device, a video display device, a measurement device, and an Internet of things (IoT) device, and in addition thereto, may be mounted on one or more of other various types of electronic devices.

In an example, the electronic apparatus 1000 may include a processor 1010, RAM 1020, the neural network device 1030, a memory 1040, a sensor module 1050, and a transmission/reception module 1060. The electronic apparatus 1000 may further include an input/output module, a security module, a power control device, and the like. A portion of hardware components of the electronic apparatus 1000 may be mounted on at least one semiconductor chip.

The processor 1010 may control the overall operation of the electronic system 1000. The processor 1010 may be configured to execute programs or applications to configure the processor 1010 to control the electronic apparatus 1000 to perform one or more or all operations and/or methods involving the acceleration of neural networks and/or analyzing input data, such as sound data, and may include any one or a combination of two or more of, for example, a central processing unit (CPU), a graphic processing unit (GPU), a neural processing unit (NPU) and tensor processing units (TPUs), but is not limited to the above-described examples.

The memory 1040 may include computer-readable instructions. The processor 1010 may be configured to execute computer-readable instructions, such as those stored in the memory 300, and through execution of the computer-readable instructions, the processor 1010 is configured to perform one or more, or any combination, of the operations and/or methods described herein. The memory 1040 may be a volatile or nonvolatile memory.

The RAM 1020 may temporarily store programs, data, or instructions. In an example, the programs and/or data stored in the memory 1040 may be temporarily stored in the RAM 1020 according to control by the processor 1010 or booting code. The RAM 1020 may be implemented as a memory such as, for example, dynamic RAM (DRAM) or SRAM.

In an example, the neural network device 1030 may perform a neural network operation using a neural network model based on received input data and generate various information signals based on a result of the operation. The neural network model may include, for example, a convolutional neural network (CNN), a recurrent neural network (RNN), a fuzzy neural network (FNN), a deep belief network, a restricted Boltzmann machine, and the like. However, examples are not necessarily limited thereto. The neural network device 1030 may be, in example, a neural network dedicated hardware accelerator (e.g., the electronic apparatus 200 with neural network acceleration) and/or a device including the neural network dedicated hardware accelerator or may be the neural network accelerator described above with reference to FIGS. 1 to 9.

The neural network device 1030 may control SRAM bit cell circuits, or circuitry, of IMC circuitry to share and/or process the same input data, and select at least a portion of operation results output from the SRAM bit cell circuits.

In an example, the term “information signal” may include one of various types of recognition signals such as a voice recognition signal, an object recognition signal, a video recognition signal, and a biological information recognition signal. In an example, the neural network device 1030 may receive, as input data, frame data included in a video stream and may generate a recognition signal about an object included in an image represented by the frame data from the frame data. The neural network device 1030 may receive various types of input data depending on the type or function of an electronic device on which the electronic system 1000 is mounted and may generate a recognition signal according to the input data.

In an example, the sensor module 1050 may collect information around the electronic apparatus 1000 on which the electronic device is mounted. The sensor module 1050 may sense or receive a signal (e.g., an image signal, a voice signal, a magnetic signal, a biosignal, a touch signal, etc.) from the outside of the electronic apparatus 1000 and convert the sensed or received signal into data. The sensor module 1050 may include at least one of various types of sensing devices such as, for example, a microphone, an imaging device, an image sensor, a light detection and ranging (LiDAR) sensor, an ultrasonic sensor, an infrared sensor, a biosensor, and a touch sensor.

The sensor module 1050 may provide the data to the neural network device 1030 as input data. In an example, the sensor module 1050 may include an image sensor, generate a video stream by photographing an external environment of the electronic system, and sequentially provide consecutive data frames of the video stream as input data to the processor 1030. However, examples are not limited thereto, and the sensor module 1050 may provide various types of data to the neural network device 1030.

In an example, the transmission/reception module 1060 may include various types of wired or wireless interfaces capable of communicating with an external device. For example, the transmission/reception module 1060 may include a wired local area network (LAN), a wireless LAN (WLAN) such as wireless fidelity (Wi-Fi), a wireless personal area network (WPAN) such as Bluetooth, a wireless universal serial bus (USB), ZigBee, near field communication (NFC), radio-frequency identification (RFID), power line communication (PLC), a communication interface accessible to a mobile cellular network, such as 3rd generation (3G), 4th generation (4G), and long term evolution (LTE), and the like.

The neural networks, accelerators, electronic apparatuses, clocks, processors, circuitry, memories, electronic apparatus 100, always-on circuitry 110, buffer circuitry 130, processor circuitry 150, electronic apparatus 200, AFE and MFCC block 220, host AP 260, NVM-based processor 240, electronic apparatus 300, electronic apparatus 310, electronic apparatus 340, electronic apparatus 500, AFE 510, pre-processor 520, second clock generator 530, NVM 550, computing logic 560, post-processing unit 570, first clock generator 580, electronic apparatus 600, memory processor 610, electronic apparatus 700, electronic apparatus 800, electronic apparatus 1000, processor 1010, RAM 1020, neural network device 13030, memory 1040, sensor module 1050, and transmission/reception module 1060 described herein and disclosed herein described with respect to FIGS. 1-10 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-10 that perform the operations described in this application may be performed by circuitry or controller computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, circuitry, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A neural network accelerator, comprising:
always-on circuitry configured to determine pre-processed data;
buffer circuitry comprising a plurality of banks configured to store the determined pre-processed data; and
processor circuitry comprising a neural network model and configured to perform power-gating, wherein the neural network model is configured to perform a neural network computation on the pre-processed data.

2. The neural network accelerator of claim 1, wherein the processor circuitry comprises a non-volatile memory (NVM) and one or more processor elements configured to perform power-gating on the NVM, and
wherein the neural network computations are executed by the one or more processor elements with respect to the stored pre-processed data and parameters of the neural network stored in the NVM.

3. The neural network accelerator of claim 2, wherein the processor circuitry comprises any one or any combination of any two or more of:
the one or more processor elements as respective one or more in-memory processor elements, within the NVM, configured to perform in-memory computing (IMC); a first clock generator configured to generate a first clock for driving the NVM and the one or more processor elements; and
a power management unit (PMU) configured to provide a power voltage for the NVM, one or more processor elements, and the first clock generator.

4. The neural network accelerator of claim 3, wherein the PMU is configured to provide the power voltage for the NVM, the one or more in-memory processor elements, and the first clock generator.

5. The neural network accelerator of claim 3, wherein the buffer circuitry comprises dual port PING-PONG static random-access memory (SRAM) configured to simultaneously perform a first operation of writing the pre-processed data into the plurality of banks through a first port and a second operation of reading the pre-processed data stored in the plurality of banks through a second port.

6. The neural network accelerator of claim 5, wherein the buffer circuitry is configured to:
operate with a second voltage and a second clock in response to performing the first operation, and
operate with a first voltage, the first voltage having a first value higher than a second voltage of the second voltage and a first clock faster than the second clock in response to performing the second operation of reading the pre-processed data stored in the plurality of banks and transferring the pre-processed data to the one or more in-memory processor elements.

7. The neural network accelerator of claim 6, wherein the buffer circuitry is configured to alternately repeat the first operation, the second operation, and a third operation of powering down until the pre-processed data is written again into the plurality of banks after the second operation is performed.

8. The neural network accelerator of claim 3, wherein the PMU is configured to turn off power to the NVM and the one or more in-memory processor elements during an idle period excluding an active period, and
wherein the processor circuitry performs the neural network computation during the active period.

9. The neural network accelerator of claim 3, wherein the PMU is configured to turn off power to the first clock generator during an idle period excluding an active period, and
wherein the processor circuitry performs the neural network computation during the active period.

10. The neural network accelerator of claim 3, wherein the first clock generator is configured to provide the first clock of a first voltage for the NVM and the one or more in-memory processor elements to operate at high speed during an active period, and
wherein the processor circuitry performs the neural network computation during the active period.

11. The neural network accelerator of claim 1, wherein the always-on circuitry is configured to provide voice data, the voice data being obtained by converting a voice audio signal into a digital signal and extracting a feature, as the pre-processed data to the processor circuitry.

12. The neural network accelerator of claim 11, wherein the always-on circuitry comprises:
an analog front end (AFE) configured to convert the voice audio signal into the digital signal;
a pre-processor circuitry configured to perform pre-processing to extract a feature of the digital signal; and
a second clock generator configured to generate a second clock for driving the AFE and the pre-processor circuitry.

13. The neural network accelerator of claim 12, further comprising:
voice activity detection (VAD) circuitry configured to determine whether the voice audio signal is present or absent,
wherein the VAD circuitry is configured to wake up the always-on circuitry responsive to a determination that the voice audio signal is present.

14. A method, the method comprising:
generating pre-processed data by converting a voice audio signal into a digital signal and extracting a feature;
storing the pre-processed data in a plurality of banks; and
performing, by a neural network model, a neural network computation on the pre-processed data.

15. The method of claim 14, wherein the performing of the neural network computation comprises:
transferring, by a first clock, the pre-processed data stored in the plurality of banks to one or more in-memory processor elements; and
performing, by the first clock, the neural network computation comprising a multiply-accumulate (MAC) computation between the pre-processed data and a stored weight.

16. The method of claim 14, wherein the storing of the pre-processed data in the plurality of banks comprises simultaneously performing a first operation of writing the pre-processed data in the plurality of banks through a first port and a second operation of reading the pre-processed data stored in the plurality of banks through a second port.

17. The method of claim 16, wherein the storing of the pre-processed data in the plurality of banks comprises:
performing the first operation with a second voltage and a second clock; and
performing the second operation of reading the pre-processed data stored in the plurality of banks with a first voltage having a first voltage value higher than a second voltage value of the second voltage and a first clock faster than the second clock and transferring the pre-processed data to one or more in-memory processor elements.

18. The method of claim 17, wherein the storing of the pre-processed data in the plurality of banks comprises alternately repeating the first operation, the second operation, and a third operation of powering down until the pre-processed data is written again into the plurality of banks after the second operation is performed.

19. The method of claim 15, the method further comprising:
turning off power to non-volatile memory (NVM) and the one or more in-memory processor elements during an idle period excluding an active period during which the neural network computation is performed.

20. The method of claim 15, the method further comprising:
providing the first clock of a first voltage for NVM and the one or more in-memory processor elements to operate at high speed in an active period in which the neural network computation is performed.
